(19) United States
(12) Patent Application Publication
(10) Pub. No.: US 2009/0078309 A1
(43) Pub. Date: Mar. 26, 2009

(54) Barrier Layers In Inverted Metamorphic Multijunction Solar Cells

(75) Inventors: Arthur Cornfeld, Sandia Park, NM (US); Mark A. Stan, Albuquerque, NM (US); Tansen Varghese, Albuquerque, NM (US); Fred Newman, Albuquerque, NM (US)

Correspondence Address: Casey Toohey;Emcore Corporation, 1600 Eubanks Blvd., SE, Albuquerque, NM, 87123, US

(73) Assignee: Emcore Corporation, Somerset, NJ (US)

(21) Appl. No.: 11/860,183

(22) Filed: Sep. 24, 2007

(51) Int. Cl. H01L 31/06; H01L 31/0248

(52) U.S. Cl. 136/255; 438/93; 257/E31.002

(57) ABSTRACT

A method of forming a multijunction solar cell including an upper subcell, a middle subcell, and a lower subcell, the method including: providing first substrate for the epitaxial growth of semiconductor material; forming a first solar subcell on the substrate having a first band gap; forming a second solar subcell over the first solar subcell having a second band gap smaller than the first band gap; forming a barrier layer over the second subcell to reduce threading dislocations; forming a grading interlayer over the barrier layer, the grading interlayer having a third band gap greater than the second band gap; and forming a third solar subcell over the grading interlayer having a fourth band gap smaller than the second band gap such that the third subcell is lattice mismatched with respect to the second subcell.

### REFERENCE TO RELATED APPLICATIONS

This application is related to co-pending U.S. patent application Ser. No. ______, entitled “Thin Inverted Metamorphic Multijunction Solar Cell with Rigid Support” filed simultaneously herewith.

This application is related to co-pending U.S. patent application Ser. No. 11/616,596 filed Dec. 27, 2006.

This application is also related to co-pending U.S. patent application Ser. No. 11/445,793 filed Jun. 2, 2006.

### GOVERNMENT RIGHTS STATEMENT

This invention was made with government support under Contract No. FA9453-06-C-0345 awarded by the U.S. Air Force. The Government has certain rights in the invention.

### BACKGROUND OF THE INVENTION

1. Field of the Invention

The present invention relates to the field of solar cell semiconductor devices, and particularly to multifunction solar cells including metamorphic layers. Such devices also include inverted metamorphic solar cells.

2. Description of the Related Art

Photovoltaic cells, also called solar cells, are one of the most important new energy sources that have become available in the past several years. Considerable effort has gone into solar cell development. As a result, solar cells are currently being used in a number of commercial and consumer-oriented applications. While significant progress has been made in this area, the requirement for solar cells to meet the needs of more sophisticated applications has not kept pace with demand. Applications such as satellites used in data communications have dramatically increased the demand for solar cells with improved power and energy conversion characteristics.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as the payloads become more sophisticated, solar cells, which act as the power conversion devices for the on-board power systems, become increasingly more important.

Solar cells are often fabricated in vertical, multifunction structures, and disposed in horizontal arrays, with the individual solar cells connected together in a series. The shape and structure of an array, as well as the number of cells it contains, are determined in part by the desired output voltage and current.

Inverted metamorphic solar cell structures such as described in M. W. Wanless et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005) present an important starting point for the development of future commercial high efficiency solar cells. The structures described in such prior art present a number of practical difficulties relating to the appropriate choice of materials and fabrication steps, in particular associated with the lattice mis-matched layers between the “lower” subcell (the subcell with the lowest band gap) and the adjacent subcell. Prior to the present invention, the materials and fabrication steps disclosed in the prior art have not been adequate to produce a commercially viable and energy efficient solar cell using an inverted metamorphic cell structure. In particular, threading dislocations propagating from the metamorphic layers present a processing challenge.

### SUMMARY OF THE INVENTION

The present invention provides a method of forming a multifunction solar cell including an upper subcell, a middle subcell, and a lower subcell, by providing first a substrate for the epitaxial growth of semiconductor material; forming a first solar subcell on the substrate having a first band gap; forming a second solar subcell over the first solar subcell having a second band gap smaller than the first band gap; forming a barrier layer over the second subcell to inhibit threading dislocations; forming a grading interlayer over the barrier layer, the grading interlayer having a third band gap greater than the second band gap; and forming a third solar subcell over the grading interlayer having a fourth band gap smaller than the second band gap and the third subcell is lattice mis-matched with respect to the second subcell.

In another aspect, the invention also provides a multifunction solar cell including a substrate; a first solar subcell on the substrate having a first band gap; a second solar subcell disposed over the first subcell and having a second band gap smaller than the first band gap; a barrier layer disposed over the second subcell; a grading interlayer disposed over the barrier layer and having a third band gap greater than the second band gap; and a third solar subcell disposed over the grading interlayer that is lattice mismatched with respect to the middle subcell and has a fourth band gap smaller than the third band gap. The barrier layer is composed of suitable material and lattice constant to inhibit or prevent threading dislocations associated with the grading interlayer from propagating.

### BRIEF DESCRIPTION OF THE DRAWINGS

The invention will be better and more fully appreciated by reference to the following detailed description when considered in conjunction with the accompanying drawings, wherein:

FIG. 1 is an enlarged cross-sectional view of a solar cell constructed according to the present invention;

FIG. 2 is a cross-sectional view of the solar cell of FIG. 1 after the next process step;

FIG. 3 is a cross-sectional view of the solar cell of FIG. 2 after the next process step;

FIG. 4 is a cross-sectional view of the solar cell of FIG. 3 after the next process step;

FIG. 5A is a cross-sectional view of the solar cell of FIG. 4 after the next process step in which the original substrate is removed;

FIG. 5B is another cross-sectional view of the solar cell of FIG. 5A with the surrogate substrate on the bottom of the Figure;

FIG. 6A is a top plan view of a wafer in which the solar cells are fabricated;

FIG. 6B is a bottom plan view of a wafer in which the solar cells are fabricated;

FIG. 7 is a top plan view of the wafer of FIG. 6B after the next process step;

FIG. 8 is a cross-sectional view of the solar cell of FIG. 5A after the next process step;

FIG. 9 is a cross-sectional view of the solar cell of FIG. 8 after the next process step;

FIG. 10 is a cross-sectional view of the solar cell of FIG. 9 after the next process step;

FIG. 11 is a cross-sectional view of the solar cell of FIG. 10 after the next process step;

FIG. 12 is a cross-sectional view of the solar cell of FIG. 11 after the next process step;

FIG. 13 is a cross-sectional view of the solar cell of FIG. 12 after the next process step;

FIG. 14 is a cross-sectional view of the solar cell of FIG. 13 after the next process step;

FIG. 15 is a cross-sectional view of the solar cell of FIG. 14 after the next process step;

FIG. 16 is an external quantum efficiency (EQE) graph of inverted metamorphic solar cell without barrier layers according to the present invention;

FIG. 17 is an EQE graph of the middle solar subcell with and without barrier layers; and

FIG. 18 is an EQE graph of an inverted metamorphic solar cell with barrier layers according to the present invention.

### DESCRIPTION OF THE PRIOR ART AND PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

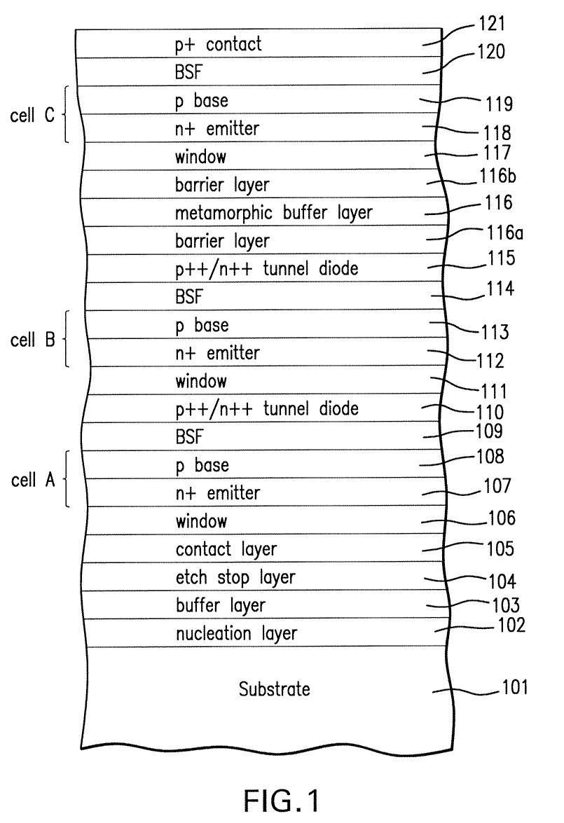

FIG. 1 depicts the multifunction solar cell according to the present invention after formation of the three subcells A, B and C on a substrate. More particularly, there is shown a substrate 101, which may be either gallium arsenide (GaAs), germanium (Ge), or other suitable material. In the case of a Ge substrate, a nucleation layer 102 is deposited on the substrate. On the substrate, or over the nucleation layer 102, a buffer layer 103, and an etch stop layer 104 are further deposited. A contact layer 105 is then deposited on layer 104, and a window layer 106 is deposited on the contact layer. The subcell A, consisting of an n+ emitter layer 107 and a p-type base layer 108, is then deposited on the window layer 106.

It should be noted that the multijunction solar cell structure could be formed by any suitable combination of group III to V elements listed in the periodic table subject to lattice constant and band gap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorous (P), arsenic (As), antimony (Sb), and bismuth (Bi).

In the preferred embodiment, the emitter layer 107 is composed of InGa(Al)P and the base layer is composed of InGa(Al)P.

The A1 term in parenthesis means that A1 is an optional constituent, and in this instance may be used in an amount ranging from 0% to 30%. On top of the base layer 108 is deposited a back surface field (“BSF”) layer 109 used to reduce recombination loss.

The BSF layer 109 drives minority carriers from the region near the base/BSF interface surface to minimize the effect of recombination loss. In other words, a BSF layer 109 reduces recombination loss at the backside of the solar subcell A and thereby reduces the recombination in the base.

On top of the BSF layer 109 is deposited a sequence of heavily doped p-type and n-type layers 110 which forms a tunnel diode which is a circuit element to connect subcell A to subcell B.

On top of the tunnel diode layers 110 a window layer 111 is deposited. The window layer 111 used in the subcell B also operates to reduce the recombination loss. The window layer 111 also improves the passivation of the cell surface of the underlying junctions. It should be apparent to one skilled in the art, that additional layer(s) may be added or deleted in the cell structure without departing from the scope of the present invention.

On top of the window layer 111 the layers of cell B are deposited: the emitter layer 112, and the p-type base layer 113. These layers are preferably composed of InGaP and Ga(In)As respectively, although any other suitable materials consistent with lattice constant and band gap requirements may be used as well.

On top of the cell B is deposited a BSF layer 114 which performs the same function as the BSF layer 109. A p++/n++ tunnel diode 115 is deposited over the BSF layer 114 similar to the layers 110, again forming a circuit element to connect cell B to cell C.

A barrier layer 116a, preferably composed of InGa(Al)P, is deposited over the tunnel diode 115, to a thickness of about 1.0 micron. Such barrier layer is intended to prevent threading dislocations from propagating, either opposite to the direction of growth into the middle and top subcells B and C, or in the direction of growth into the bottom subcell A. The barrier layer may be any combination of III-V compound semiconductor layers having a bandgap energy greater than or equal to the grading interlayer 116, and a thickness sufficient to reduce the propagation of threading dislocations. Typical materials are As, P, N or Sb based III-V semiconductor materials.

A grading interlayer or metamorphic layer 116 is deposited over the barrier layer 116a. Layer 116 is preferably a compositionally step-graded series of InGaAlAs layers with monotonically changing lattice constant that is intended to achieve a transition in lattice constant from subcell B to subcell C. The band gap of layer 116 is 1.5 eV consistent with a value slightly greater than the band gap of the middle subcell B.

A grading interlayer may be composed of any of the As, P, N, Sb based III-V compound semiconductors subject to the constraints of having the in-plane lattice parameter greater or equal to that of the second solar cell B and less than or equal to that of the third solar cell C, and having a bandgap energy greater than that of the second solar cell B.

In one embodiment, as suggested in the Wanless et al. paper, the step grade contains nine compositionally graded InGaP steps with each step layer having a thickness of 0.25 micron. In the preferred embodiment, the layer 116 is composed of InGaAlAs, with monotonically changing lattice constant, over at least nine steps.

In another embodiment of the present invention, an optional second barrier layer 116b may be deposited over the InGaAlAs metamorphic layer 116. The second barrier layer 116b will have a different composition than that of barrier layer 116a, and again the base region may be GaInAs, GaAsSb, or GaInAsN.

A window layer 117 is deposited over the barrier layer 116b, this window layer operating to reduce the recombination loss in subcell “C”. It should be apparent to one skilled in the art that additional layers may be added or deleted in the cell structure without departing from the scope of the present invention.

On top of the window layer 117, the layers of cell C are deposited: the n+ emitter layer 118, and the p-type base layer 119. These layers are preferably composed of InGaP and Ga(In)As respectively, although another suitable materials consistent with lattice constant and band gap requirements may be used as well.

A BSF layer 120 is deposited on top of the cell C, the BSF layer performing the same function as the BSF layers 109 and 114.

Finally a p+ contact layer 121 is deposited on the BSF layer 120.

It should be apparent to one skilled in the art, that additional layer(s) may be added or deleted in the cell structure without departing from the scope of the present invention.

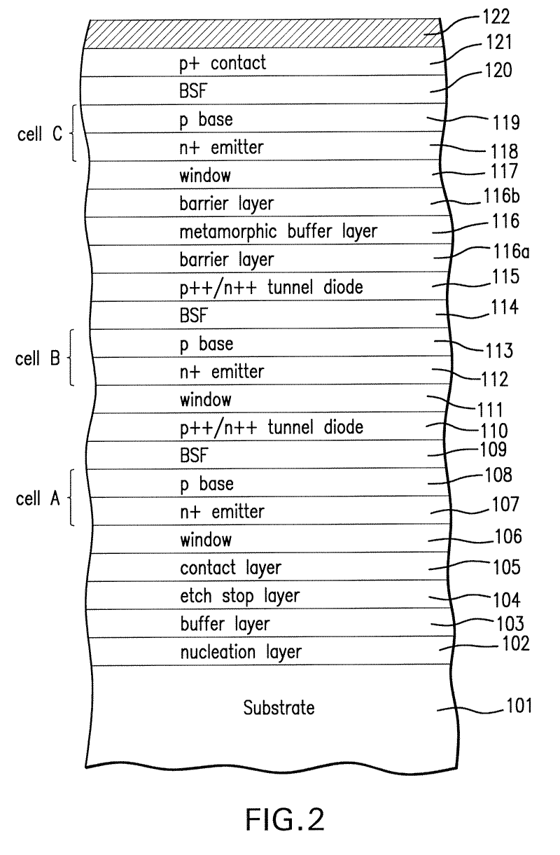

FIG. 2 is a cross-sectional view of the solar cell of FIG. 1 after the next process step in which a metal contact layer 122 is deposited over the p+ semiconductor contact layer 121. The metal is preferably Ti/Au/Ag/Au.

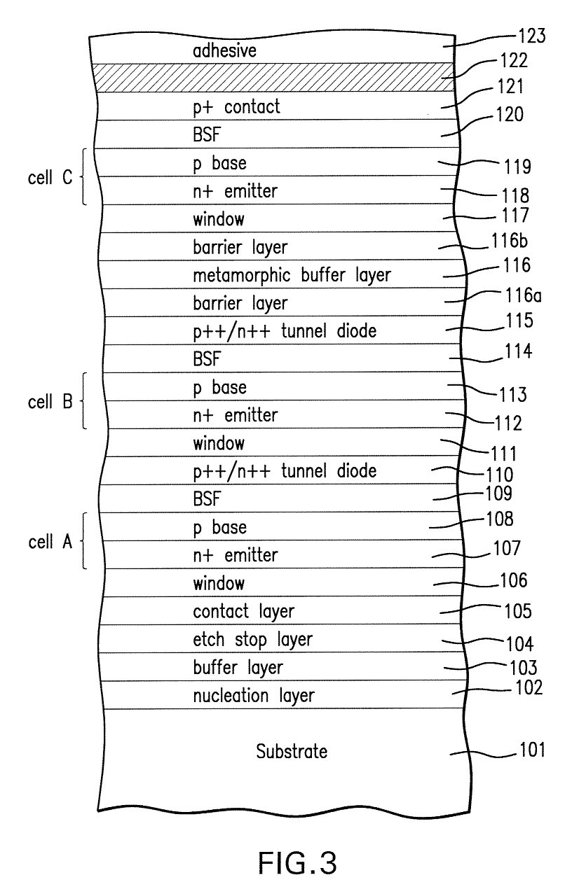

FIG. 3 is a cross-sectional view of the solar cell of FIG. 2 after the next process step in which an adhesive layer 123 is deposited over the metal layer 122. The adhesive is preferably GenTak 330 (distributed by General Chemical Corp.).

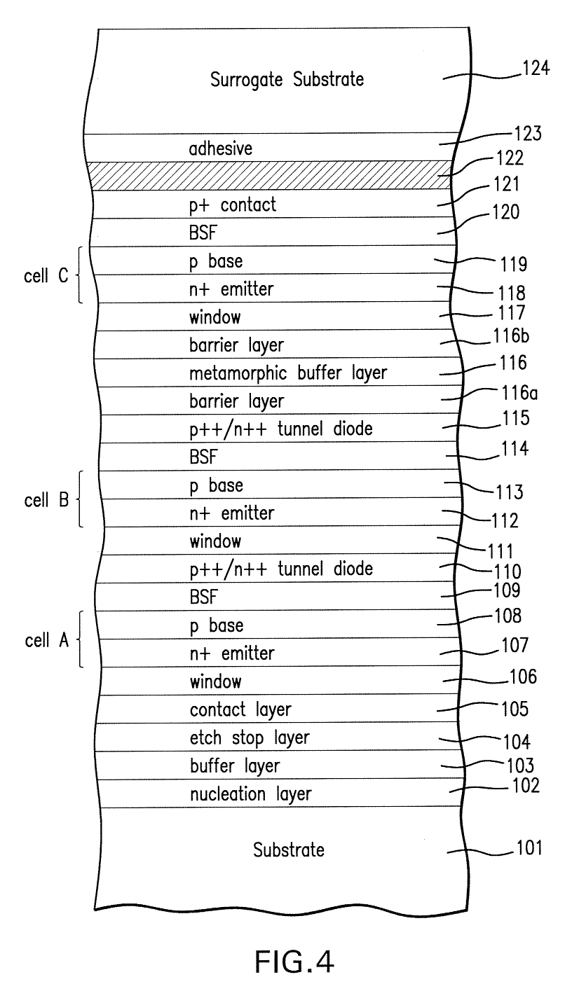

FIG. 4 is a cross-sectional view of the solar cell of FIG. 3 after the next process step in which a surrogate substrate, preferably sapphire, is attached. The surrogate substrate is about 40 mils in thickness, and is perforated with holes about 1 mm in diameter, spaced 4 mm apart, to aid in subsequent removal of the adhesive and the substrate.

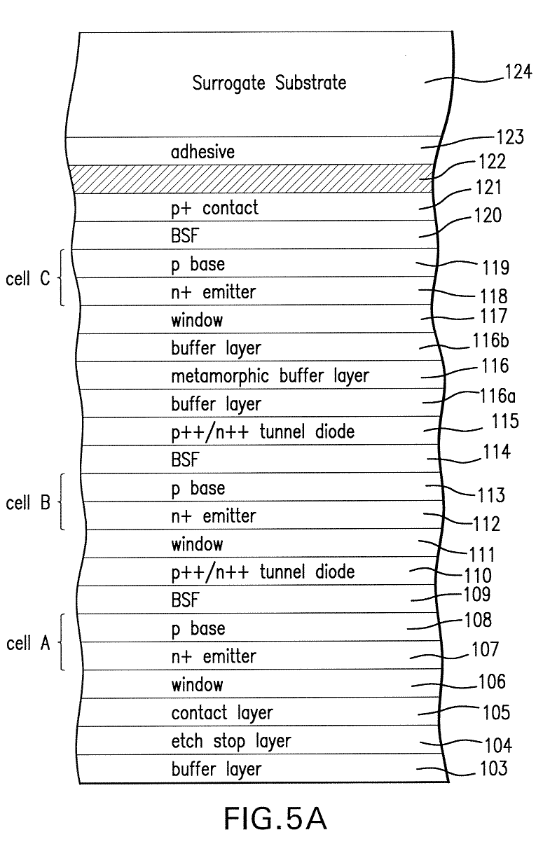

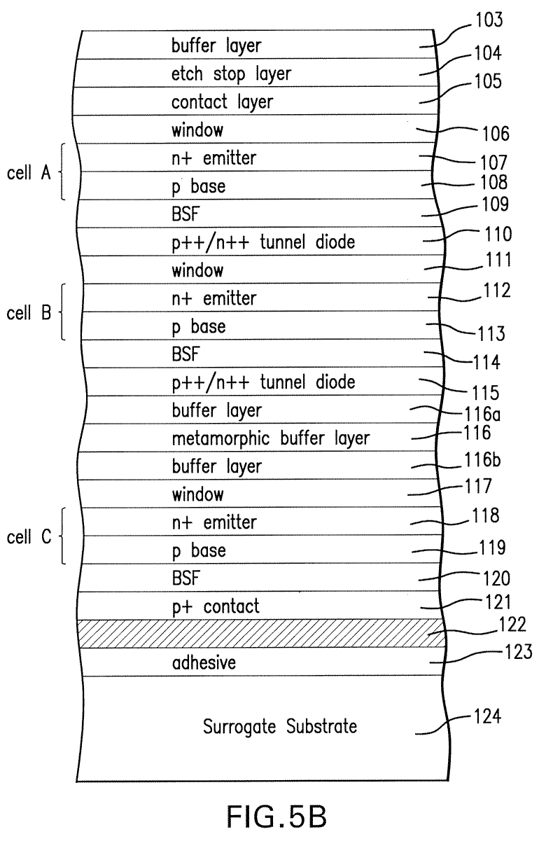

FIG. 5A is a cross-sectional view of the solar cell of FIG. 4 after the next process step in which the original substrate is removed by a sequence of lapping and/or etching steps in which the substrate 101, the buffer layer 103, and the etch stop layer 104, are removed. The etchant is growth substrate dependent.

FIG. 5B is a cross-sectional view of the solar cell of FIG. 5A from the solar cell of FIG. 5A from the orientation with the surrogate substrate 124 being at the bottom of the Figure.

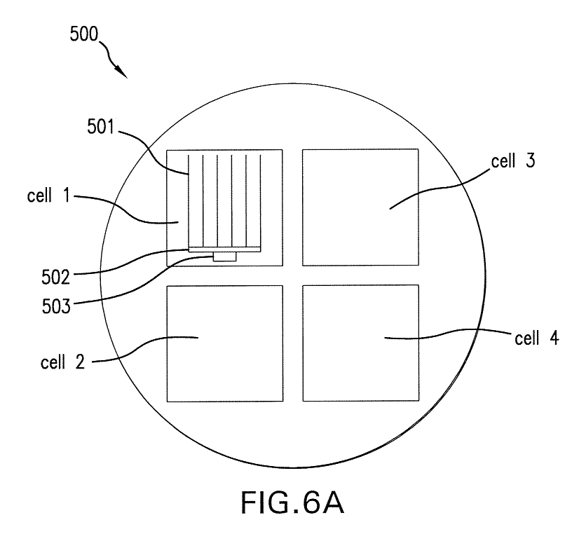

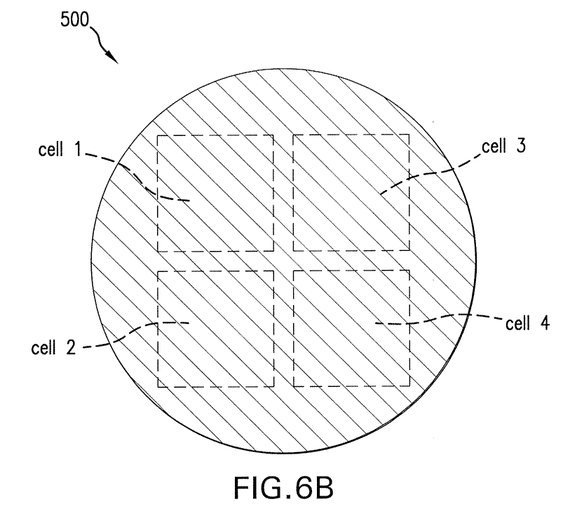

FIG. 6A is a top plan view of a wafer in which the solar cells are implemented.

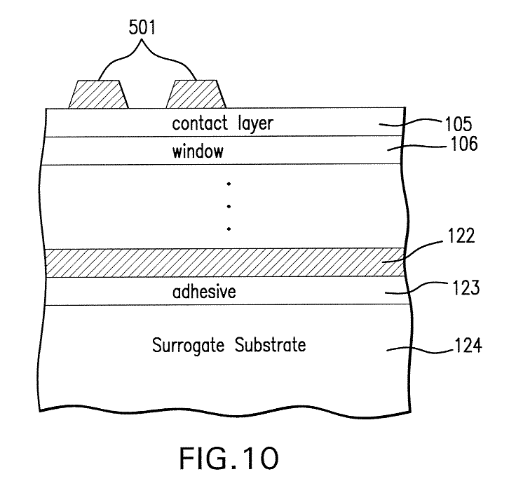

In each cell there are grid lines 501 (more particularly shown in cross-section in FIG. 10), an interconnecting bus line 502, and a contact pad 503.

FIG. 6B is a bottom plan view of the wafer with four solar cells shown in FIG. 6A.

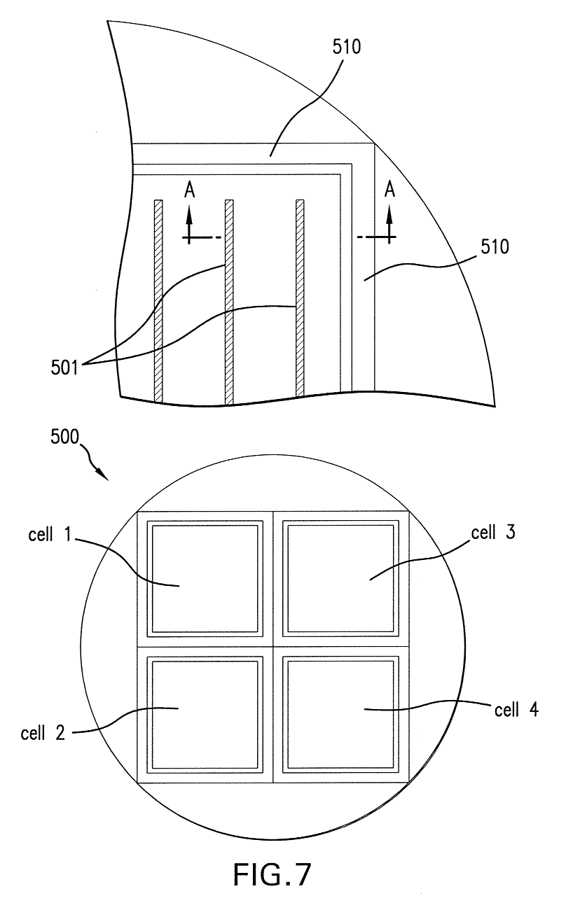

FIG. 7 is a top plan view of the wafer of FIG. 6A after the next process step in which a mesa 510 is etched around the periphery of each cell using phosphide and arsenide etchants.

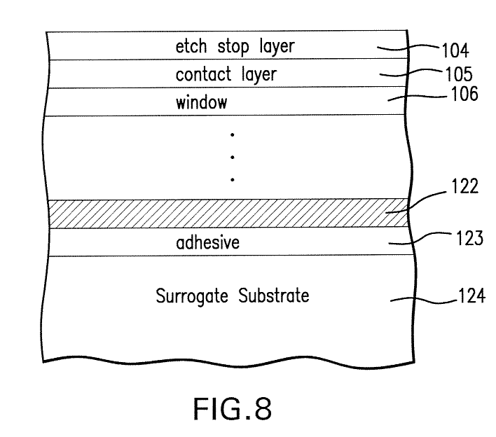

FIG. 8 is a simplified cross-sectional view of the solar cell of FIG. 5B depicting just a few of the top layers and lower layers over the surrogate substrate 124.

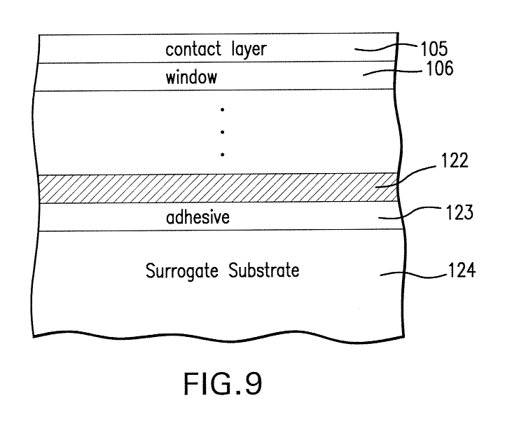

FIG. 9 is a cross-sectional view of the solar cell of FIG. 8 after the next process step in which the etch stop layer 104 is removed by a HCl/H₂O solution.

FIG. 10 is a cross-sectional view of the solar cell of FIG. 9 after the next sequence of process steps in which a photoresist mask (not shown) is placed over the contact layer 105 to form the grid lines 501. The grid lines 501 are deposited via evaporation and lithographically patterned and deposited over the contact layer 1 OS. The mask is lifted off to form the metal grid lines 501.

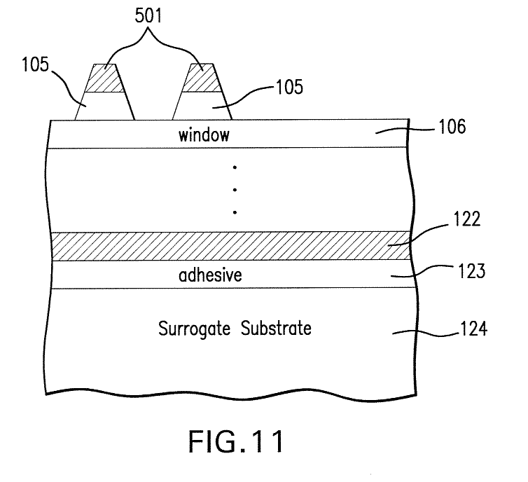

FIG. 11 is a cross-sectional view of the solar cell of FIG. 10 after the next process step in which the grid lines are used as a mask to etch down the surface to the window layer 106 using a citric acid/peroxide etching mixture.

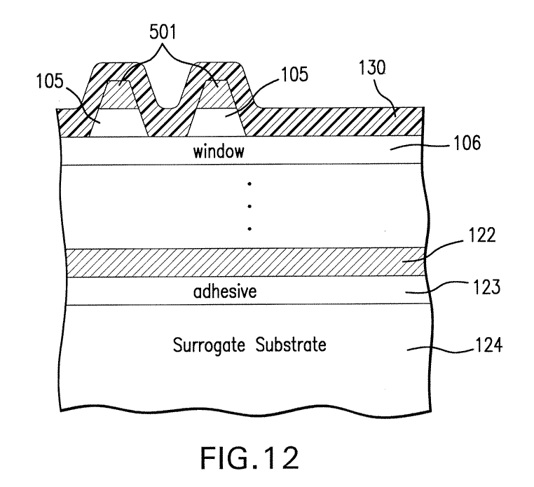

FIG. 12 is a cross-sectional view of the solar cell of FIG. 11 after the next process step in which an antireflective (ARC) dielectric coating layer 130 is applied over the entire surface of the “bottom” side of the wafer with the grid lines 501.

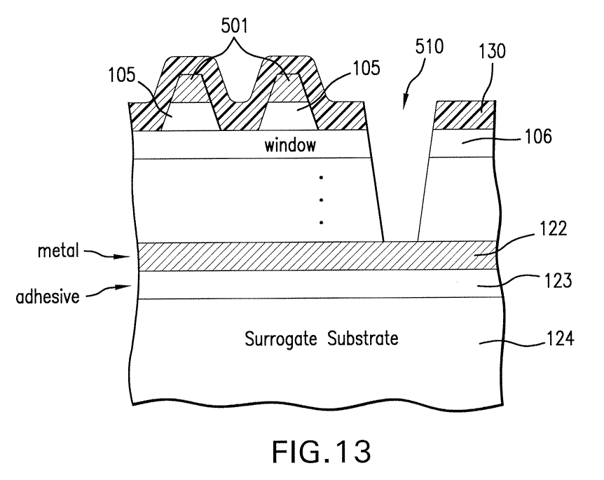

FIG. 13 is a cross-sectional view of the solar cell of FIG. 12 after the next process step in which the mesa 501 is etched down to the metal layer 122 using phosphide and arsenide etchants. The cross-section in the figure is depicted as seen from the A-A plane shown in FIG. 7. One or more silver electrodes are then welded to the contact pad(s).

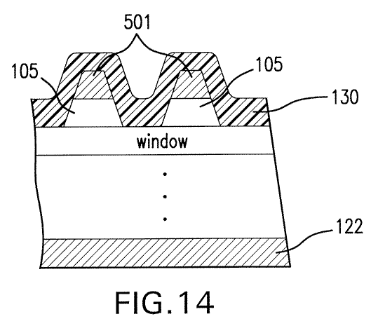

FIG. 14 is a cross-sectional view of the solar cell of FIG. 13 after the next process step after the surrogate substrate 124 and adhesive 123 are removed by EKC 922. The preferred perforations provided in the surrogate substrate have a diameter of 0.033 inches, and are separated by 0.152 inches.

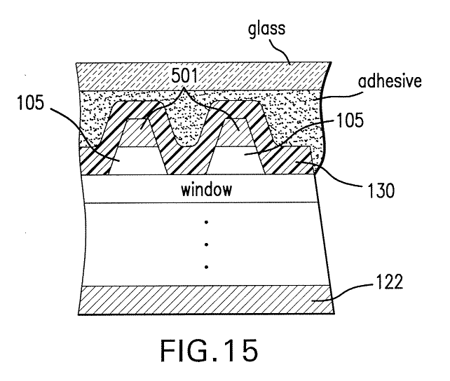

FIG. 15 is a cross-sectional view of the solar cell of FIG. 14 after the next process step in which an adhesive is applied over the ARC layer 130 and a coverglass attached thereto.

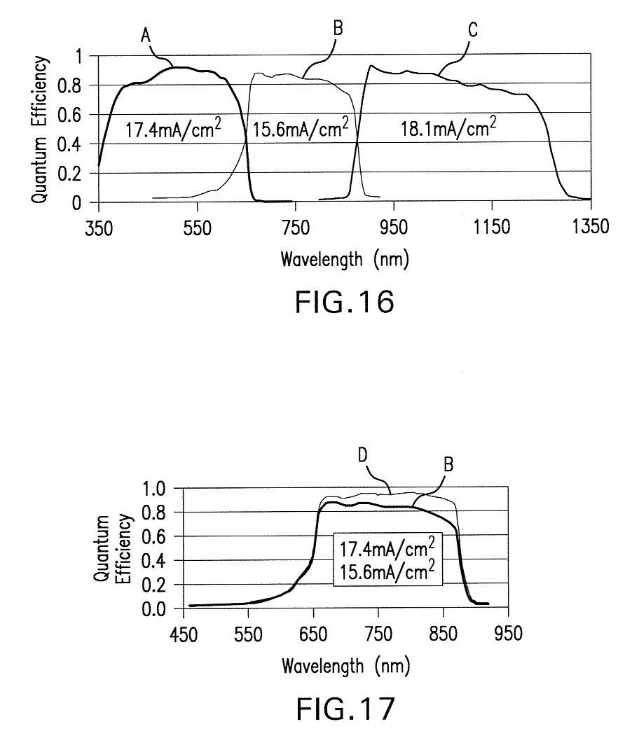

Experimented indication of the efficacy of the present invention is provided in FIGS. 16 through 18. A structure of the type shown in FIG. 1 but without barrier layers 116a and 116b was grown and fabricated into 4 cm² cells. External quantum efficiency (EQE) measurements were made and the results shown in FIG. 16 indicate that the long wavelength response of the middle subcell B was lower than expected. This observation suggested that threading dislocation propagation opposite to the direction of growth may be responsible for the degradation in the efficiency of the middle cell. Nomarski microscopy indicated unexpected cross-hatching (a mode of strain relief on the initial epitaxial layer of the lattice matched subcell A. Photoluminescence mapping further revealed that the luminescence of the middle subcell B was lower than expected. Cathodoluminescence measurements indicated that the threading dislocation density was high in the middle subcell B, but the threading dislocations did not penetrate the top subcell A. These measurements were consistent with the EQE measurements shown in FIG. 16.

FIG. 17 illustrates a comparison of the EQE measurements of a middle subcell in a triple junction solar cell with and without the addition of the barrier layer 116a according to the present invention. The graph of subcell B (without the barrier layer) has an integrated current (AMO) of 15.6 mA/cm² and lower EQE than that of subcell D (with the barrier layer), has an integrated current AMO) of 17.4 mA/cm².

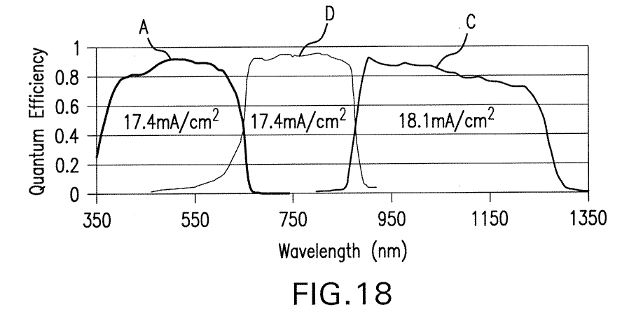

The efficacy of the use of a barrier layer in the solar cell of the present invention can be appreciated from comparing the EQE graphs of FIGS. 16 and 18. FIG. 16 is an EQE for the solar cell of FIG. 1 without a barrier layer, and FIG. 18 is an EQE for the solar cell with a barrier layer. The current of the middle subcell B of the solar cell of FIG. 18 (17.4 mA/cm²) is only slightly below the current of the top subcell C (18.4 mA/cm²). Such close current matching of the middle subcell and the top subcell demonstrates the efficacy of the present invention.

It will be understood that each of the elements described above, or two or more together, also may find a useful application in other types of constructions differing from the types of constructions described above.

Although the preferred embodiment of the present invention utilizes a vertical stack of subcells with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the present invention may utilize one or more homojunction cells or subcells, i.e., a cell or subcell in which the p-n junction is formed between a p-type semiconductor and an n-type semiconductor both of which have the same chemical composition and the same band gap, differing only in the dopant species and types. Subcell A, with p-type and n-type InGaP is one example of a homojunction subcell. Alternatively, the present invention may utilize one or more heterojunction cells or subcells, i.e., a cell or subcell in which the p-n junction is formed between a p-type semiconductor and an n-type semiconductor having different chemical compositions of the semiconductor material in the n-type and n-type regions, and/or different band gap energies in the p-type regions, in addition to utilizing different dopant species and type in the p-type and n-type regions that form the p-n junction.

The composition of the window or BSF layers may utilize other semiconductor compounds, subject to lattice constant and bandgap requirements, and may include AlInP, AlAs, AlP, AlGaInP, AlGaAsP, AlGaInAs, AlGaInPAs, GaInP, GaInAs, GaInPAs, AlGaAs, AlInAs, AlInPAs, GaAsSb, AlAsSb, GaAlAsSb, AlInSb, GaInSb, AlGaInSb, AlN, GaN, InN, GaInN, AlGaInN, GaInNAs, AlGaInNAs, ZnSSe, CdSSe, and similar materials, and still fall within the spirit of the present invention.

While the invention has been illustrated and described as embodied in a inverted metamorphic multijunction solar cell, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method of forming a multijunction solar cell comprising an upper subcell, a middle subcell, and a lower subcell, the method comprising:
providing first substrate for the epitaxial growth of semiconductor material;
forming a first solar subcell on said substrate having a first band gap;
forming a second solar subcell over said first solar subcell having a second band gap smaller than said first band gap;
forming a barrier layer over said second subcell;
forming a grading interlayer over said barrier layer, said grading interlayer having a third band gap greater than said second band gap; and
forming a third solar subcell over said grading interlayer having a fourth band gap smaller than said second band gap such that said third subcell is lattice mismatched with respect to said second subcell.

2. A method as defined in claim 1, wherein said barrier layer is composed of any As, P, N, or Sb based III-V compound semiconductors having a bandgap energy greater than or equal to that of the grading interlayer.

3. A method as defined in claim 1, further comprising forming a second barrier layer over said grading interlayer prior to the formation of said third solar subcell.

4. A method as defined in claim 3, wherein said second barrier layer is composed of any As, P, N, or Sb based III-V compound semiconductors having a bandgap energy greater than or equal to that of the grading interlayer.

5. A method as defined in claim 1, wherein said first substrate is selected from the group consisting of germanium or GaAs.

6. A method as defined in claim 1, wherein said first solar subcell is composed of an InGa(Al)P emitter region and an InGa(Al)P base region.

7. A method as defined in claim 6, wherein said second solar cell is composed of an GaInP, GaInAs, GaAsSb, or GaInAsN emitter region and an GaInAs, GaAsSb, or GaInAsN base region.

8. A method as defined in claim 1, wherein said grading interlayer is composed of any of the As, P, N, Sb based III-V compound semiconductors subject to the constraints of having the in-plane lattice parameter greater or equal to that of the second solar cell and less than or equal to that of the third solar cell, and having a bandgap energy greater than that of the second solar cell.

9. A method as defined in claim 6, wherein said second solar subcell is composed of an InGaP emitter region and an GaAs base region.

10. A method as defined in claim 1, wherein said grading interlayer is composed of InGaAlAs.

11. A method as defined in claim 8, wherein said grading interlayer is composed of nine steps of layers with monotonically changing lattice constant.

12. A method as defined in claim 1, further comprising depositing a contact layer over said third solar subcell and making electrical contact therewith.

13. A method as defined in claim 10, further comprising attaching a surrogate second substrate over said contact layer and removing the first substrate.

14. A method as defined in claim 1, further comprising:
patterning said contact layer into a grid; and
etching a trough around the periphery of said solar cell so as to form a mesa structure on said surrogate second substrate.

15. A multijunction solar cell comprising:
a substrate;
a first solar subcell on said substrate having a first band gap;
a second solar subcell disposed over said first subcell and having a second band gap smaller than said first band gap;
a barrier layer disposed over said second subcell for reducing the propagation of threading dislocations;
a grading interlayer disposed over said barrier layer and having a third band gap greater than said second band gap; and
a third solar subcell disposed over said grading interlayer that is lattice mis-matched with respect to said middle subcell and having a fourth band gap smaller than said second band gap.

16. A solar cell as defined in claim 13, wherein said barrier layer is composed of any As, P, N, or Sb based III-V compound semiconductors having a bandgap energy greater than or equal to that of the grading interlayer.

17. A solar cell as defined in claim 13, further comprising a second barrier layer disposed between said grading interlayer and said third subcell.

18. A solar cell as defined in claim 15, wherein said second barrier layer is composed of any As, P, N, or Sb based III-V compound semiconductors having a bandgap energy greater than or equal to that of the grading interlayer.

19. A solar cell as defined in claim 13, wherein the substrate is selected from the group consisting of germanium or GaAs.

20. A solar cell as defined in claim 13, wherein said first solar subcell is composed of InGa(Al)P.

21. A solar cell as defined in claim 13, wherein said second solar subcell is composed of an GaInP, GaInAs, GaAsSb, or GaInAsN emitter region and an GaInAs, GaAsSb, or GaInAsN base region.

22. A solar cell as defined in claim 13, wherein said third solar subcell is composed of InGaAs.
